(19) United States
(12) Patent Application Publication
(10) Pub. No.: US 2023/0411364 A1
(43) Pub. Date: Dec. 21, 2023

(54) ELECTRONIC PACKAGE AND MANUFACTURING METHOD THEREOF

(71) Applicant: SILICONWARE PRECISION INDUSTRIES CO., LTD., Taichung (TW)

(72) Inventors: Po-Kai HUANG, Taichung (TW); Yung-Ta LI, Taichung (TW)

(73) Assignee: SILICONWARE PRECISION INDUSTRIES CO., LTD., Taichung (TW)

(21) Appl. No.: 18/310,072

(22) Filed: May 1, 2023

(30) Foreign Application Priority Data
Jun. 17, 2022 (TW) 111122668

(51) Int. Cl. H01L 25/10; H01L 23/00; H01L 23/498; H01L 25/00; H01L 23/538; H01L 23/31; H01L 21/48

(52) U.S. Cl. CPC H01L 25/105; H01L 24/32; H01L 24/73; H01L 23/49816; H01L 23/49838; H01L 25/50; H01L 23/5385; H01L 23/5386; H01L 23/3128; H01L 21/4853; H01L 24/16; H01L 23/5381; H01L 2224/32225; H01L 2225/1058; H01L 2225/1041; H01L 2224/16227; H01L 2224/16238; H01L 2224/73204; H01L 2924/15311

(57) ABSTRACT

An electronic package is provided and includes an electronic module and a packaging module stacked on each other, where the electronic module includes a bridge component, a plurality of conductive pillars and an encapsulation layer encapsulating the bridge component and the plurality of conductive pillars, and the packaging module includes a circuit structure and a plurality of electronic elements disposed on the circuit structure, such that the packaging module is stacked on the electronic module via a plurality of supporting elements, and the plurality of electronic elements are electrically bridged with each other via the circuit structure, the plurality of supporting elements and the bridge component. Therefore, the electronic module and the packaging module are fabricated separately to prevent the bridge component from going through too many thermal processes, thereby preventing voids of the bridge component from transferring to the packaging module.

### BACKGROUND

### 1. Technical Field

The present disclosure relates to a semiconductor device, and more particularly, to an electronic package and manufacturing method thereof.

### 2. Related Art

In order to ensure continued miniaturization and versatility of electronic products and communication equipment, semiconductor packages need to be miniaturized to facilitate multi-pin connections and have great functionality. For example, in advanced packaging process, common packaging processes include 2.5D packaging process, fan-out routing with embedded bridge (FO-EB) element process, etc., where the FO-EB process has advantages of low cost and many material suppliers relative to the 2.5D packaging process.

FIG. 1 is a schematic cross-sectional view of a semiconductor package 1 of a conventional FO-EB. In the semiconductor package 1, a first semiconductor chip 11 having a plurality of conductors 110 is disposed on a substrate structure 14 having a circuit layer 140 (via an adhesive 12), and a plurality of conductive pillars 13 are disposed on the substrate structure 14, where the first semiconductor chip 11 and the plurality of conductive pillars 13 are encapsulated by a first packaging layer 15. Then, a circuit structure 10 is formed on the first packaging layer 15 and electrically connected to the first semiconductor chip 11 and the plurality of conductive pillars 13 (e.g., via conductive vias 102), a plurality of second semiconductor chips 16 are disposed on and electrically connected to the circuit structure 10 (via solder bumps 160), and the plurality of semiconductor chips 16 are encapsulated by a second packaging layer 18, wherein the circuit layer 140 and the circuit structure 10 are of fan-out redistribution layer (RDL) specification, and the first semiconductor chip 11 is served as a bridge element (a bridge die) embedded in the first packaging layer 15 to electrically bridge two adjacent ones of the second semiconductor chips 16.

Further, the semiconductor package 1 is disposed on a packaging substrate 1a via a plurality of solder balls 17 by the substrate structure 14, the plurality of conductive pillars 13 are electrically connected to the circuit layer 140, and the packaging substrate 1a is disposed on a circuit board (not shown) via solder balls 19.

However, in the conventional semiconductor package 1, the first semiconductor chip 11 encapsulates the plurality of conductors 110 via a protective layer 111, and when manufacturing multi-layer circuit of the circuit structure 10 on the first packaging layer 15, every dielectric layer 100 of the circuit structure 10 needs to be thermally cured, but the conductors 110 will generate voids during the thermal process, and the remaining voids in the conductors 110 may cause bonding issue between the conductors 110 and the circuit structure 10.

Therefore, how to overcome the aforementioned problems of the prior art has become an urgent issue to be addressed at present.

### SUMMARY

In order to address the aforementioned various deficiencies of the prior art, the present disclosure provides an electronic package, which comprises: an electronic module including an encapsulation layer, at least one bridge component embedded in the encapsulation layer and at least one conductive pillar embedded in the encapsulation layer; and a packaging module stacked on the electronic module via a plurality of supporting elements and including a circuit structure and a plurality of electronic elements disposed on the circuit structure, wherein the circuit structure is electrically connected to the bridge component and the conductive pillar via the plurality of supporting elements, and wherein the plurality of electronic elements are electrically bridged with each other via the circuit structure, the plurality of supporting elements and the bridge component.

The present disclosure also provides a manufacturing method of an electronic package, the method comprises: providing an electronic module and a packaging module, wherein the electronic module includes an encapsulation layer, at least one bridge component embedded in the encapsulation layer and at least one conductive pillar embedded in the encapsulation layer, and wherein the packaging module includes a circuit structure and a plurality of electronic elements disposed on the circuit structure; and stacking the packaging module on the electronic module via a plurality of supporting elements with the circuit structure thereof, wherein the circuit structure is electrically connected to the bridge component and the conductive pillar via the plurality of supporting elements, and wherein the plurality of electronic elements are electrically bridged with each other via the circuit structure, the plurality of supporting elements and the bridge component.

In the aforementioned electronic package and manufacturing method, the circuit structure is defined with a first block corresponding to configuration of the bridge component and a second block corresponding to configuration of the conductive pillar, such that the first block has a first conductive portion electrically connected to the bridge component, and the second block has a second conductive portion electrically connected to the conductive pillar. For instance, a line pitch of the first conductive portion and/or the second conductive portion is at most 45 μm. Alternatively, the plurality of supporting elements are defined with at least one first connecting portion electrically connected to the first block and the bridge component and at least one second connecting portion electrically connected to the second block and the conductive pillar, and wherein a width of the first connecting portion is different from a line pitch of the first conductive portion.

In the aforementioned electronic package and manufacturing method, the plurality of supporting elements are defined with at least one first connecting portion electrically connected to the bridge component and at least one second connecting portion electrically connected to the conductive pillar, such that the first connecting portion is electrically connected to the bridge component and the circuit structure, and the second connecting portion is electrically connected to the conductive pillar and the circuit structure. For instance, a width of the first connecting portion is at most 55 μm, and a width of the second connecting portion is at least 100 μm, that is, the width of the first connecting portion and the width of the second connecting portion are different. Alternatively, the width of the first connecting portion is the same as a line pitch of the bridge component.

In the aforementioned electronic package and manufacturing method, the electronic module further includes a routing structure formed on the encapsulation layer, and wherein the routing structure is electrically connected to the conductive pillar and the bridge component. The electronic module further includes a plurality of conductive elements formed on and electrically connected to the routing structure.

In the aforementioned electronic package and manufacturing method, the electronic module further includes a circuit build-up structure formed on the encapsulation layer, wherein the circuit build-up structure is electrically connected to the bridge component and the conductive pillar, and wherein the packaging module is stacked on the circuit build-up structure via the plurality of supporting elements with the circuit structure thereof.

In the aforementioned electronic package and manufacturing method, the packaging module further includes a packaging layer encapsulating the plurality of electronic elements.

In the aforementioned electronic package and manufacturing method, the present disclosure further comprises forming a packaging material between the packaging module and the electronic module to encapsulate the plurality of supporting elements.

As can be seen from the above, in the electronic package and manufacturing method thereof of the present disclosure, the electronic module and the packaging module are fabricated separately, and then the electronic module and the packaging module are stacked with each other via the supporting elements to prevent the bridge component from going through too many thermal processes. Thus, compared with the prior art, the present disclosure can prevent the problem of the bridge component generating voids.

### BRIEF DESCRIPTION OF THE DRAWINGS

FIG. 1 is a schematic cross-sectional view of a conventional semiconductor package.

FIG. 2A to FIG. 2E are schematic cross-sectional views illustrating a manufacturing method of an electronic package of the present disclosure.

FIG. 2F is a schematic cross-sectional view of a subsequent process of FIG. 2E.

FIG. 3A to FIG. 3B are schematic cross-sectional views of another aspect of FIG. 2C.

FIG. 4 is a schematic cross-sectional view of another aspect of FIG. 2B.

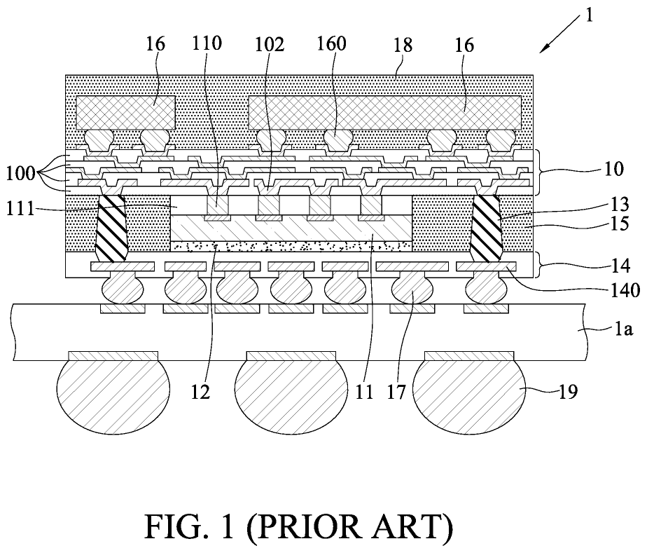

### DETAILED DESCRIPTIONS

Implementations of the present disclosure are illustrated using the following embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships, or adjustments of the sizes, are to be construed as falling within the range covered by the technical content disclosed herein to the extent of not causing changes in the technical effects created and the objectives achieved by the present disclosure. Meanwhile, terms such as “above,” “on,” “first,” “second,” “a,” “an,” “one,” and the like recited herein are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

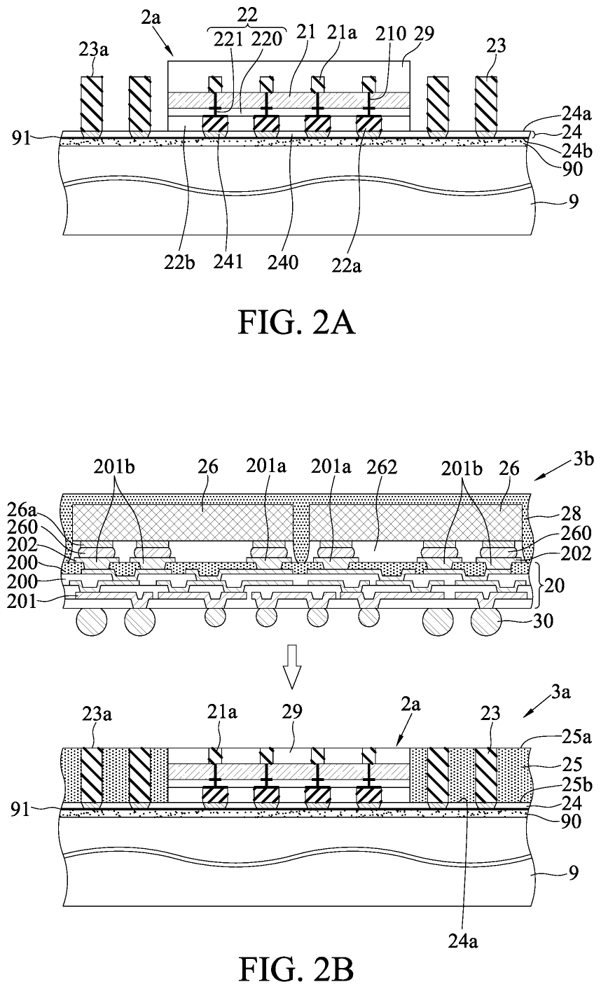

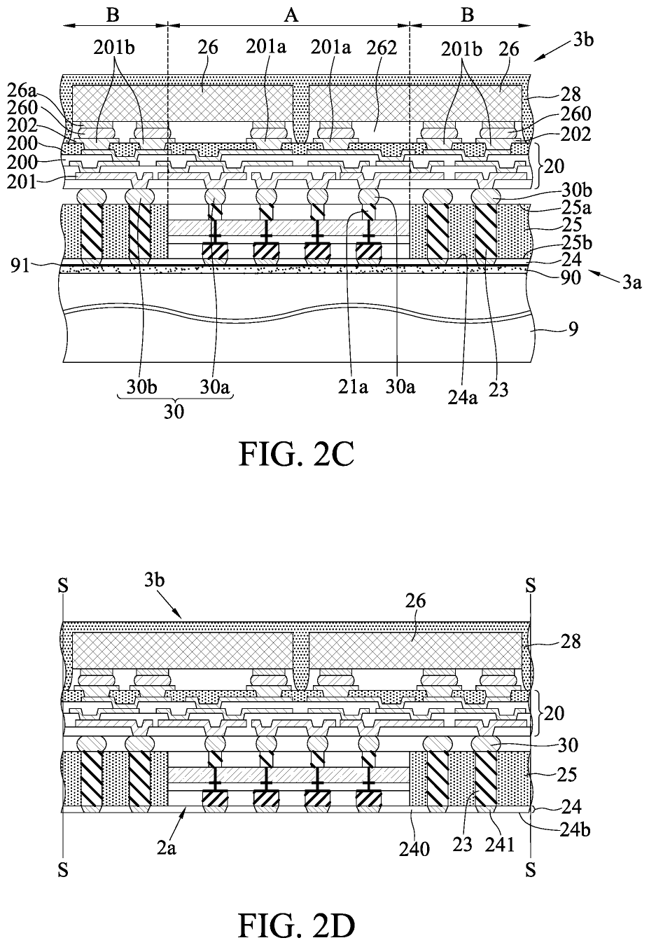

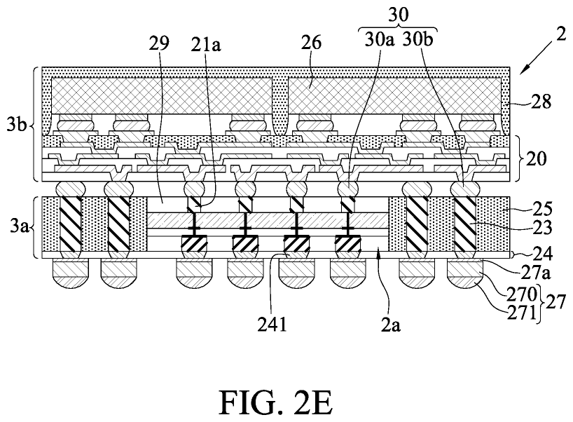

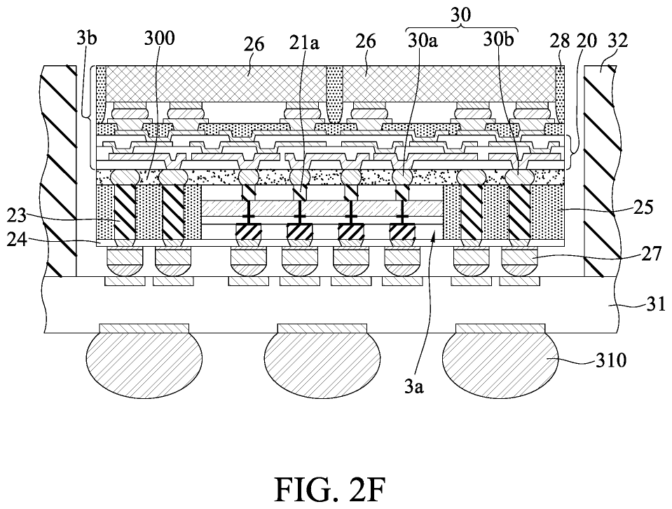

FIG. 2A to FIG. 2E are schematic cross-sectional views illustrating a manufacturing method of an electronic package 2 of the present disclosure.

As shown in FIG. 2A, a carrier 9 with a routing structure 24 is provided, and a bridge component 2a and a plurality of conductive pillars 23 are disposed on the routing structure 24.

The carrier 9 can be for example a plate of semiconductor material (such as silicon or glass), and a release layer 90 and a metal layer 91 such as titanium/copper are sequentially formed thereon by coating, such that the routing structure 24 is formed on the metal layer 91.

The routing structure 24 has a first side 24a and a second side 24b opposing the first side 24a, and the routing structure 24 is bonded to the metal layer 91 by the second side 24b thereof.

Besides, the routing structure 24 includes at least one dielectric layer 240 and a circuit layer 241 bonded to the dielectric layer 240. For example, the material for forming the dielectric layer 240 is polybenzoxazole (PBO), polyimide (PI), prepreg (PP), or other dielectric materials, and the circuit layer 241 and the dielectric layer 240 can be formed by adapting redistribution layer (RDL) process.

The bridge component 2a includes an electronic body 21, a circuit portion 22, a plurality of conductors 21a formed on the electronic body 21, and a plurality of external bumps 22a formed on the circuit portion 22 and electrically connected to the circuit portion 22 and the circuit layer 241, wherein a bonding layer 22b is formed on the circuit portion 22 to encapsulate the plurality of external bumps 22a, so that the bridge component 2a is bonded onto the first side 24a of the routing structure 24 via the bonding layer 22b, and the external bumps 22a are bonded to the circuit layer 241.

In an embodiment, the electronic body 21 is for example a semiconductor chip of a silicon-based material and has a plurality of conductive vias 210 (e.g., through-silicon vias [TSVs]) penetrating through the electronic body 21 to electrically connect to the circuit portion 22 and the plurality of conductors 21a. For instance, the circuit portion 22 includes at least one passivation layer 220 and conductive trace lines 221 bonded with the passivation layer 220, so that the conductive trace lines 221 are electrically connected to the conductive vias 210 and the plurality of external bumps 22a. It should be understood that the element structure with the conductive vias 210 has various aspects and is not particularly limited.

In addition, the conductors 21a and the external bumps 22a are metal pillars such as copper pillars, and the bonding layer 22b is a non-conductive film (NCF) or is made of other materials that are easy to adhere to the dielectric layer 240.

Additionally, a protective layer 29 can be formed on the electronic body 21 to encapsulate the plurality of conductors 21a according to requirements. For instance, the protective layer 29 is made of an insulating material, such as a nitride (e.g., silicon nitride [SiN], etc.).

The plurality of conductive pillars 23 are disposed on the first side 24a of the routing structure 24 and electrically connected to the circuit layer 241.

In an embodiment, the material for forming the plurality of conductive pillars 23 is a metal material such as copper or a solder material. For example, the plurality of conductive pillars 23 are formed by electroplating on the circuit layer 241 by means of exposure and development.

As shown in FIG. 2B, an encapsulation layer 25 is formed on the first side 24a of the routing structure 24, so that the encapsulation layer 25 encapsulates the bridge component 2a, the protective layer 29 and the plurality of conductive pillars 23 to form an electronic module 3a, wherein the encapsulation layer 25 has a first surface 25a and a second surface 25b opposing the first surface 25a, and the protective layer 29, end surfaces of the conductors 21a and end portions 23a of the conductive pillars 23 are exposed from the first surface 25a of the encapsulation layer 25, such that the encapsulation layer 25 is bonded onto the first side 24a of the routing structure 24 via the second surface 25b thereof.

In an embodiment, the encapsulation layer 25 is made of an insulating material, such as polyimide (PI), dry film, encapsulant such as epoxy resin, or molding compound. For example, the encapsulation layer 25 can be formed on the routing structure 24 by liquid compound, injection, lamination, or compression molding.

Moreover, the first surface 25a of the encapsulation layer 25 can be flush with a top surface of the protective layer 29, surfaces of the end portions 23a of the conductive pillars 23, and the end surfaces of the conductors 21a by a leveling process, so that the surfaces of the end portions 23a of the conductive pillars 23 and the end surfaces of the conductors 21a are exposed from the first surface 25a of the encapsulation layer 25. For instance, the leveling process removes part of the material of the protective layer 29, part of the material of the conductive pillars 23, part of the material of the conductors 21a and part of the material of the encapsulation layer 25 by grinding.

As shown in FIG. 2C, a packaging module 3b is provided, and the packaging module 3b is stacked on the first surface 25a of the encapsulation layer 25 of the electronic module 3a via a plurality of supporting elements 30, wherein the packaging module 3b includes a circuit structure 20 stacked on the electronic module 3a, a plurality of electronic elements 26 disposed on the circuit structure 20, and a packaging layer 28 encapsulating the plurality of electronic elements 26, so that the circuit structure 20 is electrically connected to the plurality of conductive pillars 23 and the plurality of conductors 21a via the plurality of supporting elements 30.

The circuit structure 20 is of a substrate specification and is for example a substrate having a core layer, or a coreless substrate. The circuit structure 20 may include at least one insulating layer 200 and at least one redistribution layer (RDL) 201 disposed on the insulating layer 200 (preferably at least two redistribution layers 201), wherein the outermost insulating layer 200 can be used as a solder mask layer, so that the outermost redistribution layer 201 is exposed from the solder mask layer to serve as electrical contact pads 202, such as micro pads (μ-pads).

In an embodiment, the material for forming the redistribution layer 201 is copper, and the material for forming the insulating layer 200 is a dielectric material such as polybenzoxazole (PBO), polyimide (PI), prepreg (PP), etc., or a solder-proof material such as solder mask or graphite.

In addition, the circuit structure 20 is defined with a first block A and at least one second block B, so that the redistribution layer 201 of the first block A has first conductive portions 201a, and the redistribution layer 201 of the at least one second block B has second conductive portions 201b. For example, a line pitch of each of the first conductive portions 201a or the second conductive portions 201b is less than 45 μm.

The electronic elements 26 are active elements, passive elements, or a combination of both, and the active elements are such as semiconductor chips, and the passive elements are such as resistors, capacitors, or inductors.

In an embodiment, the electronic elements 26 are semiconductor chips such as graphics processing units (GPUs), high bandwidth memories (HBMs), etc., and the bridge component 2a is served as a bridge element (a bridge die) and is electrically connected to the circuit structure 20 via the plurality of conductors 21a, thereby electrically bridging at least two electronic elements 26.

In addition, each of the electronic elements 26 has a plurality of conductive bumps 26a such as copper pillars to electrically connect the electrical contact pads 202 via a plurality of solder materials 260 such as solder bumps.

Additionally, an under bump metallurgy (UBM) layer (not shown) can be formed on the electrical contact pads 202 or the electronic elements 26 to facilitate bonding with the solder materials 260 or the conductive bumps 26a.

The packaging layer 28 is made of an insulating material, such as polyimide (PI), dry film, encapsulant such as epoxy resin, or molding compound, and the packaging layer 28 can be formed on the circuit structure 20 by lamination or molding. It should be understood that the material for forming the packaging layer 28 can be the same or different from the material for forming the encapsulation layer 25.

In an embodiment, an underfill 262 is first formed between the electronic elements 26 and the circuit structure 20 to encapsulate the plurality of conductive bumps 26a and the solder materials 260, and then the packaging layer 28 is formed to encapsulate the underfill 262 and the electronic elements 26. In other embodiments, the packaging layer 28 encapsulates the plurality of electronic elements 26 and the plurality of conductive bumps 26a at the same time without using the underfill 262.

The supporting elements 30 are defined with a plurality of first connecting portions 30a corresponding to the first block A and a plurality of second connecting portions 30b corresponding to the at least one second block B, so that the first connecting portions 30a are electrically connected to the conductors 21a of the bridge component 2a and the first conductive portions 201a of the redistribution layer 201, and the second connecting portions 30b are electrically connected to the conductive pillars 23 and the second conductive portions 201b of the redistribution layer 201.

In an embodiment, the supporting elements 30 are conductive bumps, conductive pillars, or conductive pads, etc., and the supporting elements 30 are made from metal materials such as solder material and/or copper material, but the present disclosure is not limited to as such.

Furthermore, the bridging paths of the plurality of electronic elements 26 are conducted from the first conductive portions 201a of the first block A of the circuit structure 20 to the bridge component 2a of the electronic module 3a via the first connecting portions 30a of the supporting elements 30, and the electrical paths of the plurality of electronic elements 26 are conducted from the second conductive portions 201b of the second block B of the circuit structure 20 to the conductive pillars 23 of the electronic module 3a via the second connecting portions 30b of the supporting elements 30.

Additionally, the width of the first connecting portion 30a (e.g., less than 55 μm) is different from the width of the second connecting portion 30b (e.g., more than 100 μm). Further, the width of the first connecting portion 30a (diameter or the greatest dimension) is different from the line pitch of the first conductive portion 201a, and the width of the first connecting portion 30a is the same as the line pitch of the bridge component 2a (e.g., the conductor 21a, the conductive via 210, or the conductive trace line 221).

It should be understood that the packaging module 3b is not fabricated on the electronic module 3a, such that the manufacturing process of the packaging module 3b is not limited by the specification of the carrier 9 or the electronic module 3a, thus the packaging module 3b has various manufacturing processes, and the present disclosure is not limited to as such.

As shown in FIG. 2D, the carrier 9 and the release layer 90 thereon are removed, then the metal layer 91 is removed, so as to expose the second side 24b of the routing structure 24.

In an embodiment, when peeling off the release layer 90, the metal layer 91 is served as a barrier to prevent damaging the dielectric layer 240 of the routing structure 24; and after removing the carrier 9 and the release layer 90 thereon, the metal layer 91 is removed by etching to expose the circuit layer 241.

As shown in FIG. 2E, a singulation process is performed along cutting paths S shown in FIG. 2D, and a plurality of conductive elements 27 are formed on the second side 24b of the routing structure 24, such that the plurality of conductive elements 27 are electrically connected to the circuit layer 241, thereby obtaining the electronic package 2.

In an embodiment, each of the conductive elements 27 includes a metal bump 270 (such as copper material) and a solder material 271 formed on the metal bump 270. For example, an under bump metallization (UBM) layer 27a can be formed on the circuit layer 241 to facilitate bonding with the metal bump 270. It should be understood that when the number of contacts (inputs/outputs or IOs) is insufficient, the build-up process can still be performed via RDL process to reconfigure the number of IOs and their positions in the routing structure 24.

In a subsequent process, as shown in FIG. 2F, the electronic package 2 can be disposed on a packaging substrate 31 via the plurality of conductive elements 27. Further, a ball-placement process is performed on a lower side of the packaging substrate 31 to form a plurality of solder balls 310, so that in the subsequent process, the packaging substrate 31 is disposed on a circuit board (not shown) via the solder balls 310 on the lower side of the packaging substrate 31.

Moreover, when manufacturing the packaging module 3b, part of the material of the packaging layer 28 can be removed by a leveling process such as grinding according to requirements, so that an upper surface of the packaging layer 28 is flush with upper surfaces of the electronic elements 26, as shown in FIG. 2F, such that the electronic elements 26 are exposed from the packaging layer 28.

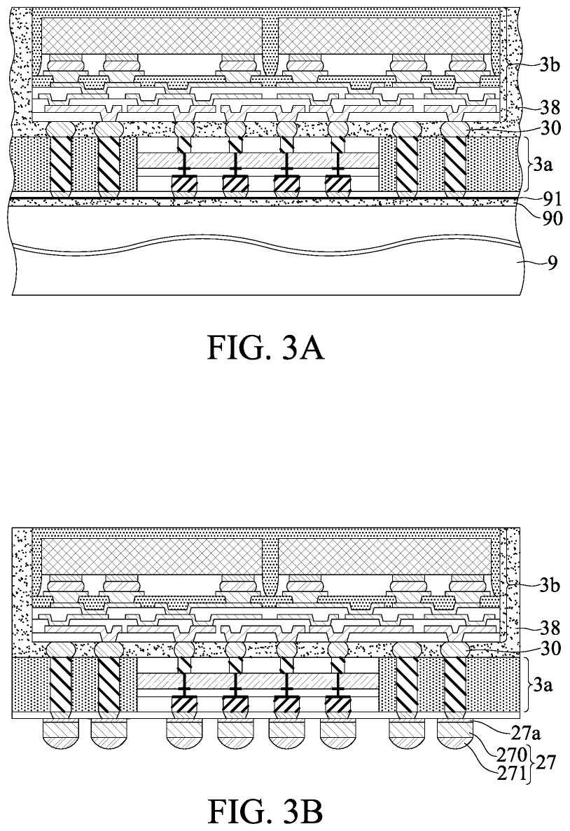

Furthermore, in the process as shown in FIG. 2C, the packaging module 3b is stacked on the electronic module 3a via the plurality of supporting elements 30, thus a packaging material 300 such as an underfill can be formed between the packaging module 3b and the electronic module 3a according to requirements, as shown in FIG. 2F, so as to encapsulate the plurality of supporting elements 30. In another aspect, as shown in FIG. 3A and FIG. 3B, the packaging module 3b and the plurality of supporting elements 30 can also be encapsulated by a packaging material 38 (e.g., an encapsulant).

In addition, at least one fastener 32 can be disposed on the packaging substrate 31 according to requirements (as shown by a metal frame in FIG. 2F), so as to eliminate the stress concentration problem and prevent the electronic package 2 from warping.

Therefore, in the manufacturing method of the present disclosure, the electronic module 3a and the packaging module 3b are fabricated separately, and then the electronic module 3a and the packaging module 3b are stacked with each other via the plurality of supporting elements 30 to prevent the bridge component 2a from going through too many thermal processes. Therefore, compared with the prior art, the manufacturing method of the present disclosure merely needs a single thermal process on the bridge component 2a (such as reflowing the plurality of supporting elements 30), and the conductors 21a will not generate voids when reflowing the plurality of supporting elements 30, thereby preventing the problem of voids in the conductors 21a caused by too many thermal processes.

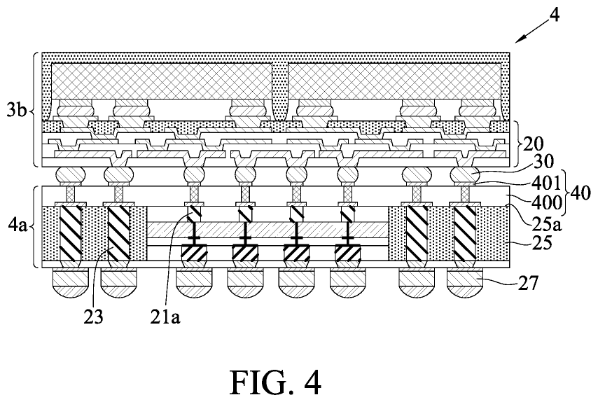

Please also refer to an electronic package 4 shown in FIG. 4, due to the electronic module 3a and the packaging module 3b are fabricated separately, the number of routing layer of the redistribution layer 201 of the circuit structure 20 of the packaging module 3b can therefore be distributed to the manufacturing process of an electronic module 4a in FIG. 4, so that a circuit build-up structure 40 is formed on the first surface 25a of the encapsulation layer 25 of the electronic module 4a, where the circuit build-up structure 40 includes at least one dielectric layer 400 and a circuit layer 401 bonded with the dielectric layer 400, so that the circuit layer 401 is electrically connected to the plurality of conductors 21a and the plurality of conductive pillars 23, and the packaging module 3b is stacked on the circuit build-up structure 40 via the plurality of supporting elements 30 with the circuit structure 20 of the packaging module 3b. In an embodiment, the circuit build-up structure 40 can be a substrate circuit structure with or without a core, or the circuit build-up structure 40 can be a redistribution structure.

Thus, by arranging routings (e.g., wirings) with a predetermined number of layers (the circuit layer 401 and the redistribution layer 201) in the circuit build-up structure 40 and the circuit structure 20 respectively, the yield of the circuit process is improved and the manufacturing cost of the electronic package 4 is reduced.

For instance, taking a predetermined five-layer routing as an example, three redistribution layers 201 can be arranged in the circuit structure 20, and two circuit layers 401 can be arranged in the circuit build-up structure 40. If the production yield of routing of each layer is about 95%, then the yield of the circuit structure 20 is 85.7% (i.e., 0.8573), and the yield of the circuit build-up structure 40 is 90.1% (i.e., 0.9025). Thus, compared with the yield of 77.4% (i.e., 0.7737) when five redistribution layers 201 are arranged in the circuit structure 20, the overall yield of the present disclosure is better, which is beneficial to lower the process cost.

The present disclosure also provides an electronic package 2, 4, comprising: an electronic module 3a, 4a, and a packaging module 3b stacked on the electronic module 3a via a plurality of supporting elements 30.

The electronic module 3a, 4a includes an encapsulation layer 25, at least one bridge component 2a embedded in the encapsulation layer 25, and at least one conductive pillar 23 embedded in the encapsulation layer 25, wherein the bridge component 2a has a plurality of conductors 21a and a protective layer 29 encapsulating the plurality of conductors 21a.

The packaging module 3b includes a circuit structure 20 and a plurality of electronic elements 26 disposed on the circuit structure 20, so that the circuit structure 20 is electrically connected to the bridge component 2a and the conductive pillar 23 via the plurality of supporting elements 30, and the plurality of electronic elements 26 are electrically bridged with the bridge component 2a via the circuit structure 20 and the supporting elements 30.

In an embodiment, the circuit structure 20 is defined with a first block A corresponding to configuration (e.g., arrangement) of the bridge component 2a and a second block B corresponding to configuration (e.g., arrangement) of the conductive pillar 23, so that the first block A has a first conductive portion 201a electrically connected to the bridge component 2a, and the second block B has a second conductive portion 201b electrically connected to the conductive pillar 23. For instance, a line pitch of the first conductive portion 201a and/or the second conductive portion 201b is at most 45 μm. Alternatively, the plurality of supporting elements 30 are defined with at least one first connecting portion 30a electrically connected to the first block A and the bridge component 2a, and at least one second connecting portion 30b electrically connected to the second block B and the conductive pillar 23, so that a width of the first connecting portion 30a is different from the line pitch of the first conductive portion 201a.

In an embodiment, the plurality of supporting elements 30 are defined with at least one first connecting portion 30a electrically connected to the bridge component 2a and at least one second connecting portion 30b electrically connected to the conductive pillar 23, so that the first connecting portion 30a is electrically connected to the bridge component 2a and the circuit structure 20, and the second connecting portion 30b is electrically connected to the conductive pillar 23 and the circuit structure 20. For instance, the width (diameter or the greatest dimension) of the first connecting portion 30a is at most 55 μm, and a width (diameter or the greatest dimension) of the second connecting portion 30b is at least 100 μm, that is, the width of the first connecting portion 30a and the width of the second connecting portion 30b are different. Alternatively, the width of the first connecting portion 30a is the same as a line pitch of the bridge component 2a.

In an embodiment, the electronic module 3a, 4a further includes a routing structure 24 formed on the encapsulation layer 25, and the routing structure 24 is electrically connected to the conductive pillar 23 and the bridge component 2a. Moreover, the electronic module 3a further includes a plurality of conductive elements 27 formed on the routing structure 24 and electrically connected to the routing structure 24.

In an embodiment, the electronic module 4a further includes a circuit build-up structure 40 formed on the encapsulation layer 25, so that the circuit build-up structure 40 is electrically connected to the bridge component 2a and the conductive pillar 23, and the packaging module 3b is stacked on the circuit build-up structure 40 via the plurality of supporting elements 30 with the circuit structure 20 of the packaging module 3b.

In an embodiment, the packaging module 3b further includes a packaging layer 28 encapsulating the plurality of electronic elements 26.

In an embodiment, the electronic package 2 further includes a packaging material 300 formed between the packaging module 3b and the electronic module 3a to encapsulate the plurality of supporting elements 30.

To sum up, in the electronic package and manufacturing method thereof of the present disclosure, the electronic module and the packaging module are fabricated separately, and then the electronic module and the packaging module are stacked with each other via the plurality of supporting elements to prevent the bridge component from going through too many thermal processes. Thus, compared with the prior art, the present disclosure can prevent the problem of the bridge component generating voids.

The above embodiments are set forth to illustrate the principles of the present disclosure and the effects thereof, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. An electronic package, comprising:
an electronic module including an encapsulation layer, at least one bridge component embedded in the encapsulation layer and at least one conductive pillar embedded in the encapsulation layer; and
a packaging module stacked on the electronic module via a plurality of supporting elements and including a circuit structure and a plurality of electronic elements disposed on the circuit structure, wherein the circuit structure is electrically connected to the bridge component and the conductive pillar via the plurality of supporting elements, and wherein the plurality of electronic elements are electrically bridged with each other via the circuit structure, the plurality of supporting elements and the bridge component.

2. The electronic package of claim 1, wherein the circuit structure is defined with a first block corresponding to configuration of the bridge component and a second block corresponding to configuration of the conductive pillar, such that the first block has a first conductive portion electrically connected to the bridge component, and the second block has a second conductive portion electrically connected to the conductive pillar.

3. The electronic package of claim 2, wherein a line pitch of the first conductive portion and/or the second conductive portion is at most 45 μm.

4. The electronic package of claim 2, wherein the plurality of supporting elements are defined with at least one first connecting portion electrically connected to the first block and the bridge component and at least one second connecting portion electrically connected to the second block and the conductive pillar, and wherein a width of the first connecting portion is different from a line pitch of the first conductive portion.

5. The electronic package of claim 1, wherein the plurality of supporting elements are defined with at least one first connecting portion electrically connected to the bridge component and at least one second connecting portion electrically connected to the conductive pillar, such that the first connecting portion is electrically connected to the bridge component and the circuit structure, and the second connecting portion is electrically connected to the conductive pillar and the circuit structure.

6. The electronic package of claim 5, wherein a width of the first connecting portion is at most 55 μm.

7. The electronic package of claim 5, wherein a width of the second connecting portion is at least 100 μm.

8. The electronic package of claim 5, wherein a width of the first connecting portion and a width of the second connecting portion are different.

9. The electronic package of claim 5, wherein a width of the first connecting portion is the same as a line pitch of the bridge component.

10. The electronic package of claim 1, wherein the electronic module further includes a routing structure formed on the encapsulation layer, and wherein the routing structure is electrically connected to the conductive pillar and the bridge component.

11. The electronic package of claim 10, wherein the electronic module further includes a plurality of conductive elements formed on and electrically connected to the routing structure.

12. The electronic package of claim 1, wherein the electronic module further includes a circuit build-up structure formed on the encapsulation layer, wherein the circuit build-up structure is electrically connected to the bridge component and the conductive pillar, and wherein the packaging module is stacked on the circuit build-up structure via the plurality of supporting elements with the circuit structure thereof.

13. The electronic package of claim 1, wherein the packaging module further includes a packaging layer encapsulating the plurality of electronic elements.

14. The electronic package of claim 1, further comprising a packaging material formed between the packaging module and the electronic module to encapsulate the plurality of supporting elements.

15. A method of manufacturing an electronic package, comprising:
providing an electronic module and a packaging module, wherein the electronic module includes an encapsulation layer, at least one bridge component embedded in the encapsulation layer and at least one conductive pillar embedded in the encapsulation layer, and wherein the packaging module includes a circuit structure and a plurality of electronic elements disposed on the circuit structure; and
stacking the packaging module on the electronic module via a plurality of supporting elements with the circuit structure thereof, wherein the circuit structure is electrically connected to the bridge component and the conductive pillar via the plurality of supporting elements, and wherein the plurality of electronic elements are electrically bridged with each other via the circuit structure, the plurality of supporting elements and the bridge component.

16. The method of claim 15, wherein the circuit structure is defined with a first block corresponding to configuration of the bridge component and a second block corresponding to configuration of the conductive pillar, such that the first block has a first conductive portion electrically connected to the bridge component, and the second block has a second conductive portion electrically connected to the conductive pillar.

17. The method of claim 16, wherein a line pitch of the first conductive portion and/or the second conductive portion is at most 45 μm.

18. The method of claim 16, wherein the plurality of supporting elements are defined with at least one first connecting portion electrically connected to the first block and the bridge component and at least one second connecting portion electrically connected to the second block and the conductive pillar, and wherein a width of the first connecting portion is different from a line pitch of the first conductive portion.

19. The method of claim 15, wherein the plurality of supporting elements are defined with at least one first connecting portion electrically connected to the bridge component and at least one second connecting portion electrically connected to the conductive pillar, such that the first connecting portion is electrically connected to the bridge component and the circuit structure, and the second connecting portion is electrically connected to the conductive pillar and the circuit structure.

20. The method of claim 19, wherein a width of the first connecting portion is at most 55 μm.

21. The method of claim 19, wherein a width of the second connecting portion is at least 100 μm.

22. The method of claim 19, wherein a width of the first connecting portion and a width of the second connecting portion are different.

23. The method of claim 19, wherein a width of the first connecting portion is the same as a line pitch of the bridge component.

24. The method of claim 15, wherein the electronic module further includes a routing structure formed on the encapsulation layer, and wherein the routing structure is electrically connected to the conductive pillar and the bridge component.

25. The method of claim 24, wherein the electronic module further includes a plurality of conductive elements formed on and electrically connected to the routing structure.

26. The method of claim 15, wherein the electronic module further includes a circuit build-up structure formed on the encapsulation layer, wherein the circuit build-up structure is electrically connected to the bridge component and the conductive pillar, and wherein the packaging module is stacked on the circuit build-up structure via the plurality of supporting elements with the circuit structure thereof.

27. The method of claim 15, wherein the packaging module further includes a packaging layer encapsulating the plurality of electronic elements.

28. The method of claim 15, further comprising forming a packaging material between the packaging module and the electronic module to encapsulate the plurality of supporting elements.
